(19) United States
(12) Patent Application Publication
(10) Pub. No.: US 2012/0243324 A1
(43) Pub. Date: Sep. 27, 2012

(54) NON-VOLATILE SEMICONDUCTOR STORAGE DEVICE

(75) Inventor: Hidefumi NAWATA, Kawasaki-shi (JP)

(73) Assignee: Kabushiki Kaisha Toshiba, Tokyo (JP)

(21) Appl. No.: 13/223,569

(22) Filed: Sep. 1, 2011

(30) Foreign Application Priority Data
Mar. 23, 2011 (JP) 2011-064129

(51) Int. Cl. G11C 16/10; G11C 16/06; G11C 16/04

(52) U.S. Cl. 365/185.19; 365/185.18; 365/185.22

(57) ABSTRACT

A non-volatile semiconductor storage device according to one embodiment includes a memory cell array that has NAND cell units in which a plurality of memory cells connected in series, the control gate of each of the plurality of memory cells being connected to a word line, and a control circuit configured to execute a write operation by applying a certain write voltage to the word line multiple times to set a threshold voltage of the memory cell to a value corresponding to data. The control circuit is configured to control the write voltage such that the write voltage is increased by a first step-up voltage when the write voltage is repeatedly applied in a first period after the write operation starts, and the write voltage is increased by a second step-up voltage lower than the first step-up voltage in a second period after the first period.

### CROSS REFERENCE TO RELATED APPLICATION

This application is based upon and claims the benefit of priority from prior Japanese Patent Application No. 2011-64129, filed on Mar. 23, 2011, the entire contents of which are incorporated herein by reference.

### BACKGROUND

1. Field

Embodiments described herein relate generally to a non-volatile semiconductor storage device that is electrically rewritable.

2. Description of the Related Art

With an increasing use of a large capacity of data such as images and videos in mobile devices, the demand for NAND type flash memories is rapidly increasing. In particular, by adopting a multi-valued storage technology for storing information of 2 bits or more in a memory cell, a larger capacity of information can be stored with a small chip area.

In highly integrated flash memories with the advancement of miniaturization of cells, a selected memory cell to which a write operation is not completed receives interference by an adjacent memory cell the channel of which is boosted with the completion of the write operation. As a result, a threshold voltage distribution that indicates data of the selected memory cell is influenced by the interference. In particular, when a multi-valued storage system is adopted, the width and the distance of the threshold voltage distributions are narrowly set as compared with a two-valued storage system. For this reason, the interference of the adjacent cells greatly affects reliability of data.

### BRIEF DESCRIPTION OF THE DRAWINGS

FIG. 1 is a block diagram illustrating the schematic configuration of a non-volatile semiconductor storage device according to a first embodiment;

FIG. 2 is a circuit diagram illustrating the configuration of a memory cell array 1 illustrated in FIG. 1;

FIG. 3 is a circuit diagram illustrating the configuration of a sense amplifier SA illustrated in FIG. 2;

FIG. 4 is a diagram illustrating an example of written data in a four-valued storage flash memory;

FIG. 5 is a flowchart illustrating a data write sequence according to a comparative example;

FIG. 6 is a diagram illustrating a voltage at the time of a write operation according to the comparative example;

FIG. 7 is a diagram illustrating a voltage at the time of a write operation according to the comparative example;

FIG. 8A is a diagram illustrating an influence by interference of adjacent cells in the comparative example;

FIG. 8B is a diagram illustrating an influence by interference of adjacent cells in the comparative example;

FIG. 9 is a diagram illustrating an influence by interference of adjacent cells in the comparative example;

FIG. 10 is a flowchart illustrating a data write sequence according to the first embodiment;

FIG. 11 is a diagram illustrating a voltage at the time of a write operation according to the first embodiment;

FIG. 12 is a graph illustrating an effect of a data write operation according to the first embodiment;

FIG. 13 is a graph illustrating an effect of a data write operation according to the first embodiment;

FIG. 14 is a graph illustrating an effect of a data write operation according to the first embodiment;

FIG. 15 is a flowchart illustrating a data write sequence according to a second embodiment; and

FIG. 16 is a flowchart illustrating a data write sequence according to a third embodiment.

### DETAILED DESCRIPTION

A non-volatile semiconductor storage device according to one embodiment includes a memory cell array that has NAND cell units in which a plurality of memory cells each having a control gate and a charge accumulating layer are connected in series, one end of the NAND cell unit being connected to a bit line through a first select gate transistor, the other end thereof being connected to a source line through a second select gate transistor, the control gate of each of the plurality of memory cells being connected to a word line and gates of the first and second select gate transistors being connected to first and second select gate lines, respectively, and a control circuit configured to execute a write operation by applying a certain write voltage to the word line multiple times to set a threshold voltage of the memory cell to a value corresponding to data. The control circuit is configured to control the write voltage such that the write voltage is increased by a first step-up voltage when the write voltage is repeatedly applied in a first period after the write operation starts, and the write voltage is increased by a second step-up voltage lower than the first step-up voltage in a second period after the first period.

Next, non-volatile semiconductor storage devices according to embodiments will be described with reference to the drawings.

### First Embodiment

[Configuration]

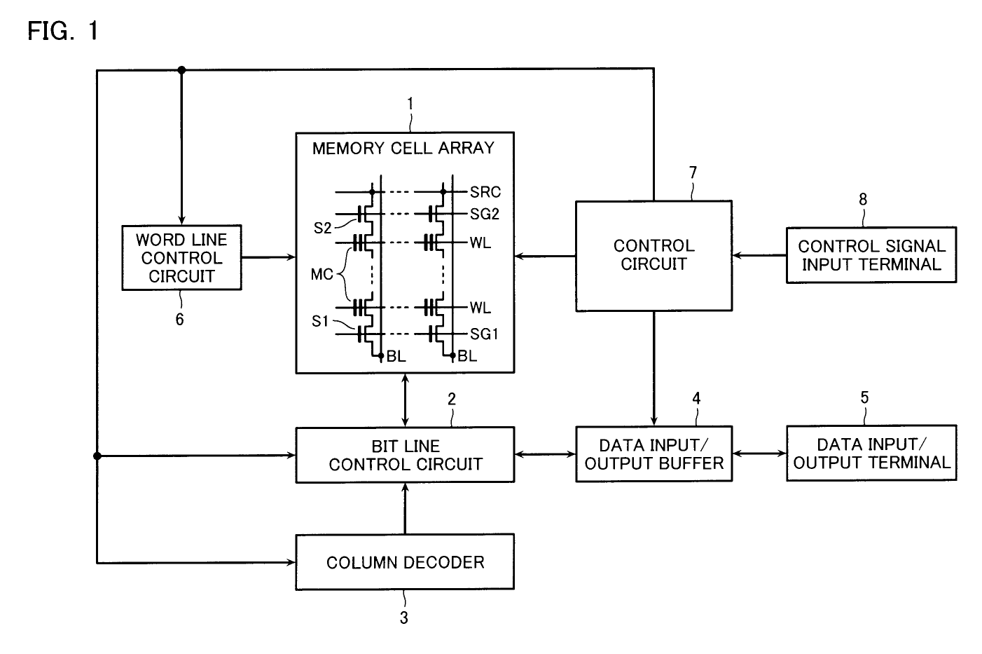

FIG. 1 illustrates the configuration of a non-volatile semiconductor storage device according to a first embodiment. The non-volatile semiconductor storage device is a NAND type flash memory that adopts a four-valued storage system. The non-volatile semiconductor storage device includes a memory cell array 1 in which memory cells MC to store data are disposed in a matrix. The memory cell array 1 includes a plurality of bit lines BL, a plurality of word lines WL, a source line SRC, and a plurality of memory cells MC. Each of the memory cell MC has a stack gate structure that has a floating gate functioning as a charge accumulating layer to accumulate charge and a control gate connected to the word line WL. The memory cells MC are configured such that data is electrically rewritable by charging or discharging of the floating gate, and are disposed in a matrix at intersections of the bit lines BL and the word lines WL.

To the memory cell array 1, a bit line control circuit 2 that controls a voltage of the bit line BL and a word line control circuit 6 that controls a voltage of the word line WL are connected. In this case, the bit line control circuit 2 reads data of the memory cells MC in the memory cell array 1 through the bit line BL. The bit line control circuit 2 applies a control voltage to the memory cells MC in the memory cell array 1 through the bit line BL and executes a write operation on the memory cells MC.

To the bit line control circuit 2, a column decoder 3 and a data input/output buffer 4 are connected. The data read from the memory cells MC of the memory cell array 1 is output from the data input/output terminal 5 to the outside through the data input/output buffer 4. Further, write data input from the outside to the data input/output terminal 5 is input to the bit line control circuit 2 through the data input/output buffer 4 and is written in the designated memory cell MC.

The memory cell array 1, the bit line control circuit 2, the column decoder 3, the data input/output buffer 4, and the word line control circuit 6 are connected to a control circuit 7. The control circuit 7 generates a control signal to control the memory cell array 1, the bit line control circuit 2, the column decoder 3, the data input/output buffer 4, and the word line control circuit 6, according to a control signal input to a control signal input terminal 8.

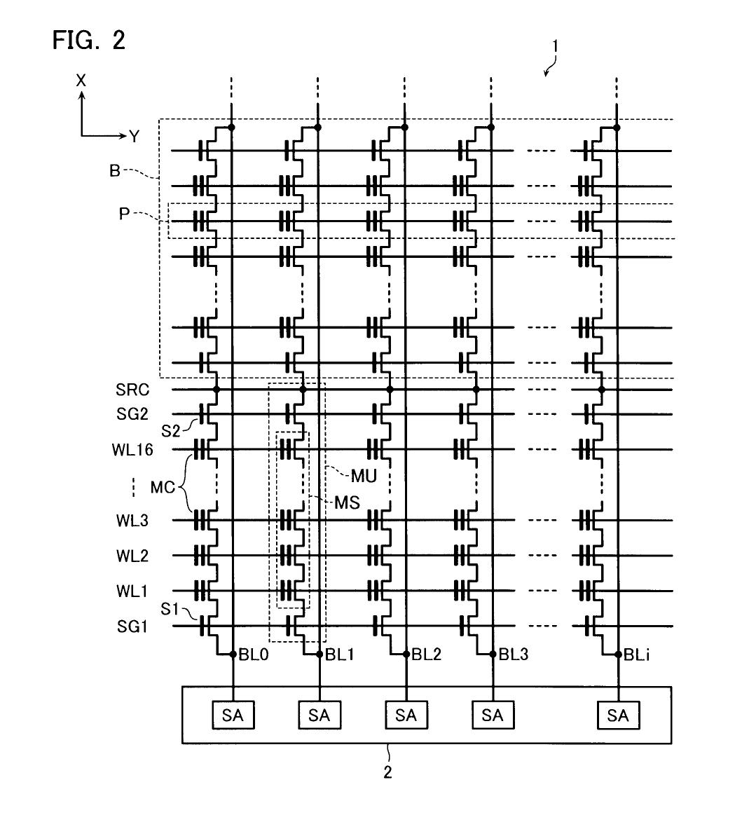

FIG. 2 illustrates the configuration of the memory cell array 1 illustrated in FIG. 1. As illustrated in FIG. 2, the memory cell array 1 is configured by a plurality of blocks B. In the memory cell array 1, data is erased (block erasing processing) by the block B basis. As illustrated in FIG. 2, the block B is configured to include a plurality of memory units MU. One memory unit MU is configured to include a memory string MS including, for example, 16 memory cells MC connected in series and first and second select gate transistors S1 and S2 connected to both ends of the memory string MS, respectively. One end of the first select gate transistor S1 is connected to the bit line BL and one end of the second select gate transistor S2 is connected to the source line SRC. Control gates of the memory cells MC that are disposed in line in a Y direction are commonly connected to any one of the word lines WL1 to WL16. Further, control gates of the first select gate transistors S1 that are disposed in line in the Y direction are commonly connected to a select gate line SG1 and control gates of the second select gate transistors S2 that are disposed in line in the Y direction are commonly connected to a select gate line SG2. A set P of a plurality of memory cells MC that are connected to one word line WL constitutes one page or multiple pages. For each set P, data is written and read.

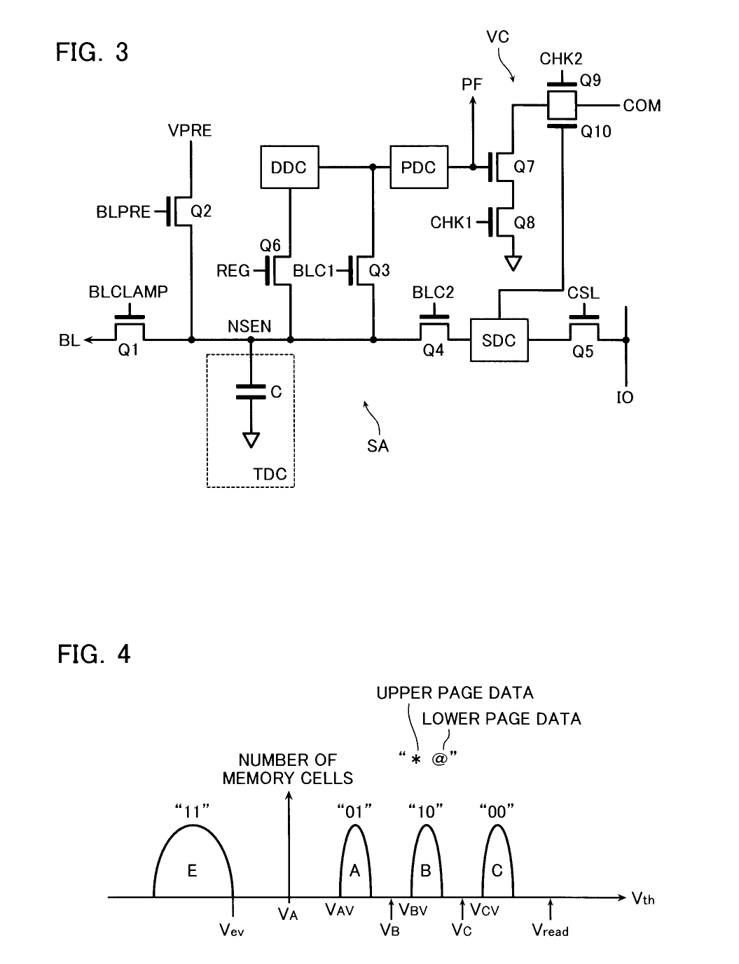

The data is written and read using sense amplifiers SA provided in the bit line control circuit 2. The bit line control circuit 2 includes the sense amplifier SA illustrated in FIG. 3, for each bit line BL. In this manner, this embodiment is suitable for a NAND type flash memory of an all bit line (ABL) system that is carried out simultaneously by all the bit lines BL constituting one page which is a read unit of data. The sense amplifier SA senses and amplifies data that is read from the memory cell MC to the bit line BL, when the data is read. The sense amplifier SA applies a voltage corresponding to write data to the bit line BL, when the data is written.

The configuration of the sense amplifier SA will be described using FIG. 3. FIG. 3 is a circuit diagram illustrating the sense amplifier SA according to the first embodiment. FIG. 3 illustrates the configuration corresponding to one bit line in particular.

As illustrated in FIG. 3, the sense amplifier SA has four data caches, that is, a temporary data cache (TDC), a primary data cache (PDC), a secondary data cache (SDC), and a dynamic data cache (DDC).

A node NSEN of the cache TDC is a sense node to sense a voltage of the bit line BL and is a data storage node to temporarily store data. The cache TDC has a capacitor C that accumulates charge needed for the data sense in the sense node NSEN. The cache TDC is connected to the bit line BL through a clamping transistor Q1. The clamping transistor Q1 clamps the voltage of the bit line BL at the time of reading data and transfers the voltage to the sense node NSEN. To the sense node NSEN, a precharging transistor Q2 to precharge the bit line BL and the node NSEN is connected.

The sense node NSEN is connected to the cache PDC and the cache SDC through transmitting transistors Q3 and Q4, respectively. The cache PDC is a data storage circuit that holds read data and write data. The cache SDC is a data cache that is disposed between the cache PDC and a data line IO and is used to temporarily hold the write data or the read data. A data line-side node of the cache SDC is connected to the data line IO through a select gate transistor Q5 driven by a column selection signal CSL.

The data is written by repeating a write voltage application operation and a write verification operation, in order to obtain a certain threshold value distribution. The write verification operation is executed for each bit and write data of a next cycle needs to be determined by the verification result. The cache DDC serve as a data cache that temporarily saves and holds the write data held by the cache PDC at the time of writing data. By the transistor Q6, data of the sense node NSEN can be set according to the data held by the cache DDC.

To the cache PDC, a verification check circuit VC is connected. The verification check circuit VC has transistors Q7, Q8, Q9, and Q10. The transistor Q7 is a checking transistor, and a gate thereof is connected to an output node of the cache PDC, a source thereof is connected to a ground through the transistor Q8 controlled by a check signal CHK1, and a drain thereof is connected to a common signal line COM common to sense units corresponding to one page through the transmitting transistors Q9 and Q10 to be provided in parallel. Gates of the transistors Q9 and Q10 are controlled by a check signal CHK2 and an output node of the cache SDC.

As the verification read result, when a write operation does not end, a level of the output node of the cache PDC becomes “H” (=“1”). The “H” level is held as a write completion flag PF. Thereby, the checking transistor Q7 is turned on and discharges charge of the common signal line COM, which is previously charged with “H”, along a path of the transistors Q9 and Q10 to Q7 to Q8. As the verification read result, when the write operation ends, the level of the output node of the cache PDC becomes “L” (=“0”) and the checking transistor Q7 is turned off. Therefore, if the write operation corresponding to one page is completed, the level of the output node of the cache PDC becomes “0”, the common signal line COM holds an “H” level without discharging the charge, and the “H” level becomes information that indicates write completion.

[Data Storage System]

Next, the data storage system of the non-volatile semiconductor storage device will be schematically described. The non-volatile semiconductor storage device is configured such that threshold voltages of the memory cells MC have four distributions.

FIG. 4 illustrates a relationship between four-valued data (data “11”, “01”, “10”, and “00”) of two bits stored in the memory cells MC of the non-volatile semiconductor storage device and threshold voltage distributions of the memory cells MC. As illustrated in FIG. 4, 2-bit data of one memory cell MC includes lower page data and upper page data. When the 2-bit data is represented as “* [symbol] ”, “*” indicates the upper page data and “ [symbol] ” indicates the lower page data.

In FIG. 4, voltages VA, VB, and VC are voltages that are applied to the selected word lines WL when four kinds of data are read. Voltages VAV, VBV, and VCV represent verification voltages that are applied to verify whether the write operation is completed, when the write operation is executed with threshold voltage distributions A, B, or C. A voltage Vread represents a read voltage that is applied to a non-selected memory cell MC of the memory string MS when data is read and makes a current flow through the non-selected memory cell MC, regardless of data held in the non-selected memory cell MC. A voltage Vev is an erase verification voltage that is applied to the memory cell MC to verify whether an erase operation is completed, when data of the memory cell MC is erased. A magnitude relationship between the voltages described above is Vev<VA<VAV<VB<VBV<VC<VCV<Vread.

In a threshold voltage distribution E of the memory cells MC after a block is erased, an upper limit value is a negative value and data “11” is allocated. The memory cells MC that show data “01”, “10”, and “00” in a write state constitute the positive threshold voltage distributions A, B, and C, respectively (that is, lower limit values of the distributions A, B, and C are positive values). The threshold voltage distribution A of the data “01” has a lowest voltage, the threshold voltage distribution C of the data “00” has a highest voltage, and the threshold voltage distribution B of the data “10” has an intermediate voltage of the data “01” and the data “00”.

[Write Operation According to a Comparative Example]

First, before the first embodiment is described, a write operation of a non-volatile semiconductor storage device according to the comparative example will be described. During a data write operation, a high electric field is applied to a tunnel oxide film of the memory cell MC to inject electrons into a floating gate electrode and a threshold voltage Vth of the memory cell MC is increased by a certain amount. Specifically, with respect to the selected memory cell MC where the write operation is executed, a voltage Vss is set to a channel of the selected memory cell MC through the bit line BL. With respect to the selected memory cell MC where the write operation is not executed, a voltage Vboost is set to the channel of the selected memory cell MC through the bit line BL. Then, a write voltage Vpgm is applied to the selected word line WL. Thereby, the electrons are injected only into the floating gate electrode of the selected memory cell MC where the voltage Vss is set to the channel. By repeating the electron injection operation and the verification operation, the electrons are repeatedly injected until the threshold voltage Vth of the memory cell MC becomes the certain verification voltages (VAV, VBV, and VCV). As a result, data is written in the memory cell MC.

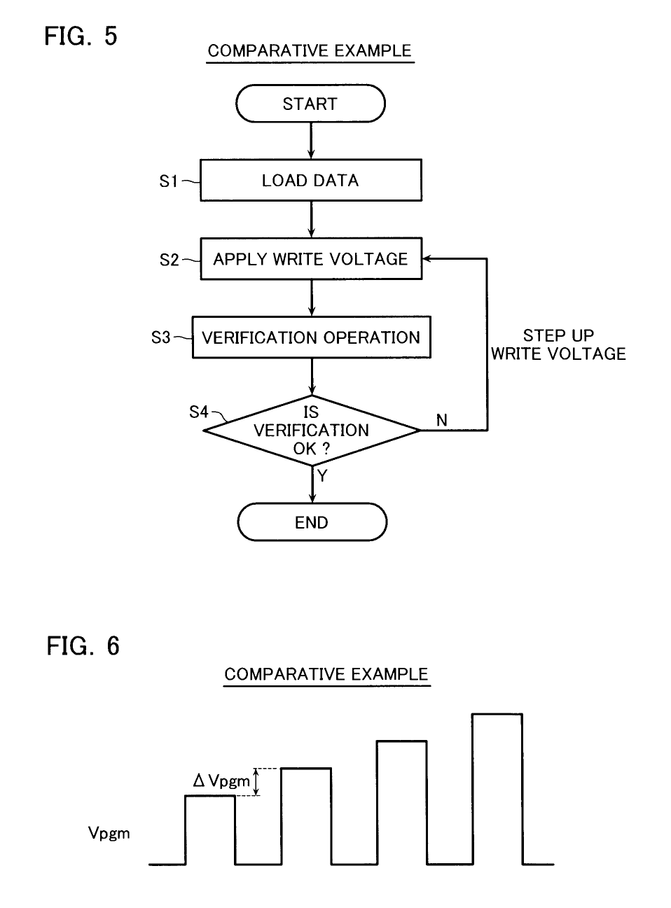

FIG. 5 is a flowchart illustrating the write operation according to the comparative example. The write operation is executed in order from a lower page to an upper page. First, when the write operation starts, the data of the lower page is loaded to the cache SDC of the sense amplifier SA (refer to FIG. 3) and the loaded data is transferred from the cache SDC to the cache PDC (step S1). In the case where a gate voltage BLCLAMP of the bit line clamping transistor Q1 is set to Vdd+Vth, when data “H” (non-write) is stored in the cache PDC, the potential of the bit line BL becomes Vdd and the transistor Q1 is turned off. Meanwhile, when data “L” (write) is stored in the cache PDC, the potential of the bit line BL becomes Vss. The voltage Vdd is applied to the select gate lines SG1 and SG2 of the selected block B, a voltage Vpass (for example, 10 V) is applied to the non-selected word lines WL, and a write voltage Vpgm (for example, 20 V) is applied to the selected word line WL (step S2). Thereby, when the voltage of the bit line BL is the voltage Vss, the write operation is executed, because the voltage of the channel of the selected memory cell MC becomes the voltage Vss and the voltage of the word line WL becomes the voltage Vpgm. Meanwhile, when the voltage of the bit line BL is the voltage Vdd, the channel of the selected memory cell MC is boosted to the voltage Vpgm/2 by coupling with the floating gate and the write operation is prohibited.

Then, the verification operation is executed to read whether the threshold voltage of the selected memory cell MC is more than a certain verification voltage (step S3). That is, the sense node NSEN is precharged with a voltage VPRE (=Vdd) through the precharging transistor Q2, the bit line clamping transistor Q1 is turned on, and the bit line BL is charged with the voltage Vdd. By applying the certain verification voltage to the selected word line WL where the write operation is executed and determining whether the bit line BL is discharged, it is determined whether the threshold voltage of the selected memory cell MC is more than the certain verification voltage.

During the verification operation, when it is determined that the threshold voltage of the selected memory cell MC is more than the certain verification voltage and desired data is written in the selected memory cell MC, the data write operation ends (step S4). At this time, since the cache TDC holds an “H” level, the “H” level is held in the cache PDC through the transistor Q3 and a level of the write completion flag PF becomes “H”. At this time, since the “H” level held in the cache PDC is held in the cache TDC through the cache DDC, the subsequent write operation is not executed.

Meanwhile, during the verification operation, when it is determined that the threshold voltage of the selected memory cell MC is the certain verification voltage or less and data is not written in the selected memory cell MC, an “L” level is held in the cache TDC. Therefore, the voltage of the channel of the selected memory cell MC becomes the voltage Vss through the bit line BL and the write voltage Vpgm is applied again to the selected memory cell MC (steps S4 and S2). In this case, when the write voltage Vpgm is applied again, the write voltage may be increased (stepped up).

FIG. 6 illustrates the write voltage Vpgm at the time of the write operation according to the comparative example. As illustrated in FIG. 6, the write voltage Vpgm is increased by a step-up voltage ΔVpgm (for example, 0.3 V), whenever the write voltage application operation is repeated.

Next, the write operation of the upper page is executed. During the write operation of the upper page, almost the same operation as that of the above case is executed.

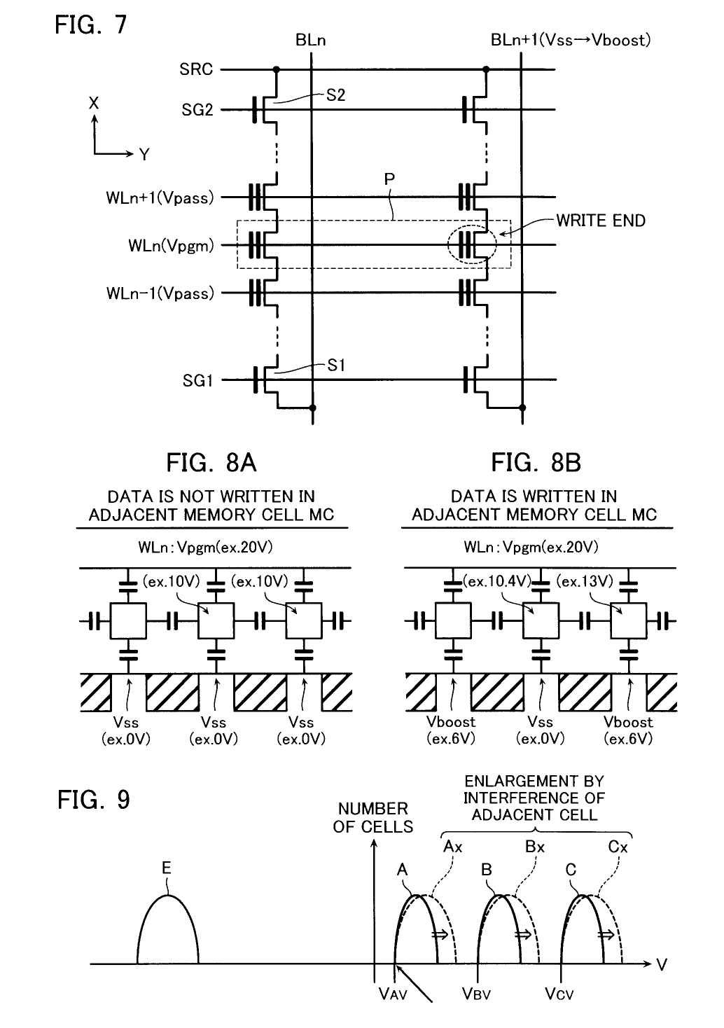

FIG. 7 illustrates a bit line voltage at the time of the write operation according to the comparative example described above. The write operation with respect to the memory cell MC is executed by a set P basis as illustrated in FIG. 7. That is, data is collectively written in all of the memory cells MC connected to one word line WL. Among the plurality of memory cells MC in the set P, in the memory cell MC where the threshold voltage increases to a desired value, it is determined that the write operation ends and the electron injection operation with respect to the floating gate electrode is stopped. In this case, the voltage of the bit line BL that is connected through the select gate transistor S1 increases from the voltage Vss to the voltage Vboost. The voltage Vboost is transferred to the channel of the memory cell MC. The select gate transistor S1 is turned off after transferring the voltage Vboost to the channel. As a result, even though the write voltage Vpgm is applied, the large potential difference is not generated between the channel and the floating gate electrode and the electrons are not injected.

In this case, in the memory cell MC that is adjacent in a direction of the word line WL to the memory cell MC of which the write operation is completed, a threshold voltage distribution indicating data is affected by interference of the memory cell MC where the data is completely written. Hereinafter, an influence by the interference of the adjacent memory cell will be described. FIGS. 8A and 8B illustrate the influence by the interference of the adjacent memory cell. FIGS. 8A and 8B illustrate a cross-section of the memory cell array 1 of FIG. 7 taken along a Y direction. As illustrated in FIGS. 8A and 8B, when the write operation is executed on the memory cells MC connected to a selected word line WLn, the write voltage Vpgm is applied to the selected word line WLn and electrons are injected into the floating gate electrode.

During the write operation that is executed by the set P basis, by influence of the adjacent memory cell MC to which the write operation is completed, the voltage of the floating gate electrode of the memory cell MC changes. That is, the step width of the write voltage that is applied to the non-written memory cell MC is changed by the voltage Vboost applied to the channel of the written memory cell MC through the bit line BL. This phenomenon is hereinafter called “interference of the adjacent cell”. This phenomenon becomes remarkable when the distance between the memory cells MC decreases.

For example, as illustrated in FIG. 8A, when the data write operation with respect to the memory cell MC adjacent to the memory cell MC where data is to be written does not end, the voltage Vss is applied to the channels of the memory cells MC including the adjacent memory cell MC. In this case, by applying the write voltage Vpgm (for example, 20 V) to the word line WL, the voltage of the floating gate electrode of the memory cell MC increases to about 10 V. Hereinafter, the voltage of the floating gate electrode is increased with the step-up voltage of about 0.15 V corresponding to the step-up voltage ΔVpgm. By the potential difference between the channel and the floating gate electrode, electrons are injected into the floating gate electrode.

Meanwhile, as illustrated in FIG. 8B, when the data write operation with respect to the memory cell MC adjacent to the memory cell MC where data is to be written ends, the voltage Vboost (for example, 6 V) is applied to the channel of the adjacent memory cell MC where the data write operation ends. In this case, by applying the write voltage Vpgm (for example, 20 V) to the word line WL, the voltage of the floating gate electrode of the adjacent memory cell MC increases to about 13 V. As a result, the voltage of the floating gate electrode of the non-written memory cell MC is affected by coupling of the floating gate of the adjacent memory cell MC, and increases to about 10.4 V by the write voltage Vpgm (for example, 20 V) with respect to the word line WL and the voltage (for example, 13 V) of the adjacent floating gate electrode. This means that the step-up voltage ΔVpgm greatly changes from 0.15 V to 0.55 V, before and after the write operation with respect to the adjacent memory cell MC ends. If the write operation immediately after the step-up voltage changes is not associated with an end of the write operation of the memory cell MC where data is to be written, the change of the step-up voltage can be absorbed at the time of a next write operation. However, when the write operation of the memory cell MC ends by the write operation immediately after the step-up voltage changes, the threshold voltage of the memory cell MC may be greatly shifted in a positive direction. Hereinafter, the memory cell MC where the write operation ends by the write operation immediately after the step-up voltage changes is called a “final change memory cell MCE”.

In this manner, the threshold voltage of the memory cell MC greatly changes when the voltage Vboost is applied to the channel of the adjacent memory cell MC. Meanwhile, when the channel of the adjacent memory cell MC is held at the voltage Vss, the change of the threshold voltage of the memory cell MC is small. In the memory cell MC where the write operation ends by application of a following write voltage Vpgm+n*ΔVpgm after the voltage Vboost is applied to the channel of the adjacent memory cell MC, the threshold voltage greatly changes and the write operation ends. As a result, the memory cell MC where the data write operation ends at write timing when the shift amount of the threshold voltage is large arises.

Accordingly, as illustrated in FIG. 9, the threshold voltage distribution A of the memory cell MC becomes a threshold voltage distribution Ax that has the larger distribution width due to the interference of the adjacent memory cell MC. In this case, a lower limit value of the threshold voltage distribution Ax is almost equal to a lower limit value of the original threshold voltage distribution A (refer to arrow of FIG. 9). For the same reason, the threshold voltage distributions B and C become threshold voltage distributions Bx and Cx that have the larger distribution widths, respectively. Lower limit values of the threshold voltage distributions Bx and Cx are almost equal to lower limit values of the original threshold voltage distributions B and C. In this way, the threshold voltage distributions Ax, Bx, and Cx where the distribution widths are increased cause erroneous read or the like.

[Write System According to the First Embodiment]

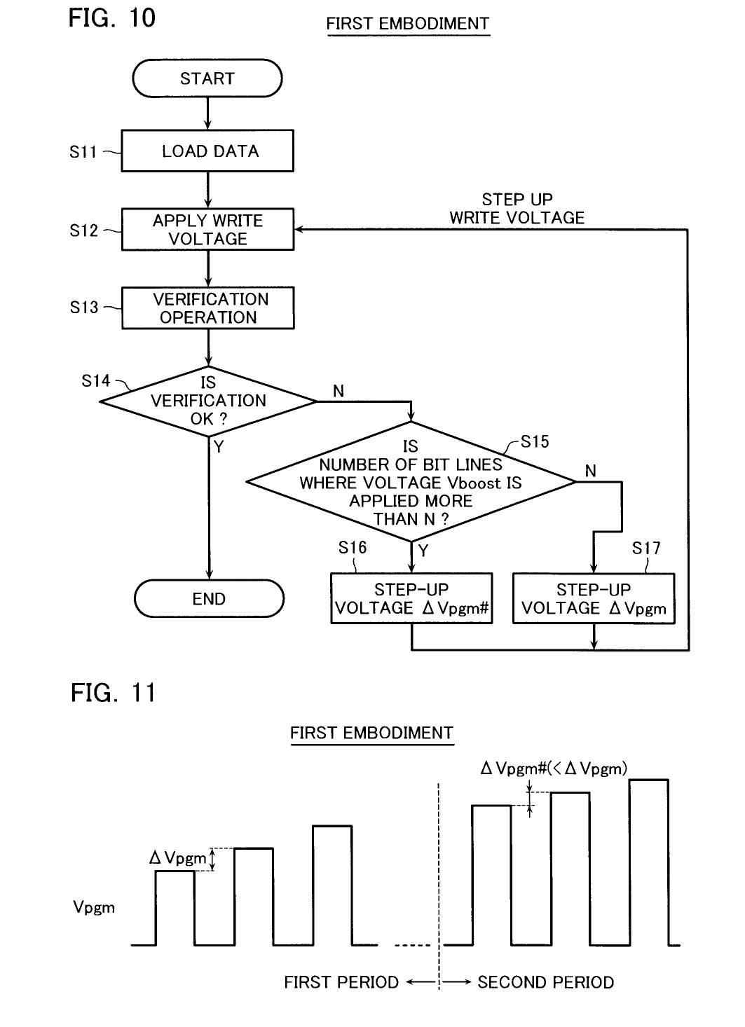

In the first embodiment, a write system illustrated in FIGS. 10 and 11 is adopted in view of the problem of the write system according to the comparative example. Following processing is executed by the control circuit 7.

The write system according to the first embodiment is the same as the write system according to the comparative example in that the write voltage application operation and the verification operation are repeatedly executed. However, the write system according to the first embodiment is different from the write system according to the comparative example in that the step-up voltage to be increased in each step when the write voltage is repeatedly applied is adjusted on the basis of a certain condition. The value of the step-up voltage is set on the basis of the number of memory cells MC where the write operation ends, that is, the number of memory cells MC where the voltage Vboost is applied to the channel through the bit line BL.

The write operation according to this embodiment will be described with reference to FIG. 10. FIG. 10 is a flowchart illustrating the write operation according to this embodiment. The write operation is executed in order of a lower page and an upper page. First, when the write operation starts, the data of the lower page is loaded to the cache SDC of the sense amplifier SA (refer to FIG. 3) and the loaded data is transferred from the cache SDC to the cache PDC (step S11). In the case where the gate voltage BLCLAMP of the bit line clamping transistor Q1 is set to Vdd+Vth, when data “H” (non-write) is stored in the cache PDC, the potential of the bit line BL becomes Vdd and the transistor Q1 is turned off. Meanwhile, when data “L” (write) is stored in the cache PDC, the potential of the bit line BL becomes Vss. The voltage Vdd is applied to the select gate lines SG1 and SG2 of the selected block B, the voltage Vpass (for example, 10 V) is applied to the non-selected word lines WL, and the write voltage Vpgm (for example, 20 V) is applied to the selected word line WL (step S12). Thereby, when the voltage of the bit line BL is the voltage Vss, the write operation is executed, because the voltage of the channel of the selected memory cell MC becomes the voltage Vss and the voltage of the word line WL becomes the voltage Vpgm. Meanwhile, when the voltage of the bit line BL is the voltage Vdd, the channel of the selected memory cell MC is boosted to the voltage Vpgm/2 by coupling with the floating gate and the write operation is prohibited.

Then, the verification operation is executed to read whether the threshold voltage of the selected memory cell MC is more than the certain verification voltage (step S13). That is, the sense node NSEN is precharged with the voltage VPRE (=Vdd) through the precharging transistor Q2, the bit line clamping transistor Q1 is turned on, and the bit line BL is charged with the voltage Vdd. By applying the certain verification voltage to the selected word line WL where the write operation is executed and determining whether the bit line BL is discharged, it is determined whether the threshold voltage of the selected memory cell MC is more than the certain verification voltage.

During the verification operation, when it is determined that the threshold voltage of the selected memory cell MC is more than the certain verification voltage and desired data is written in the selected memory cell MC, the data write operation ends (Y in step S14). At this time, since the cache TDC holds an “H” level, the “H” level is held in the cache PDC through the transistor Q3 and a level of the write completion flag PF becomes an “H”. At this time, since the “H” level held in the cache PDC is held as the “H” level in the cache TDC through the cache DDC, the subsequent write operation is not executed.

Meanwhile, during the verification operation, when it is determined that the threshold voltage of the selected memory cell MC is the certain verification voltage or less and data is not written in the selected memory cell MC, the process proceeds to an operation for counting the number of memory cells MC where the write operation ends (N in step S14). In this case, the number of memory cells MC where the write operation ends can be found by counting the number of write completion flags PF (corresponding to the number of bit lines BL where the voltage Vboost is applied) of which a level becomes an “H” level (step S15). When the number of bit lines BL where the voltage Vboost is applied is the certain number N or less, the step-up voltage is maintained at the voltage ΔVpgm (for example, 0.3 V), the write voltage is stepped up, and the write voltage is applied to the memory cell MC (step S17). when the number of bit lines BL where the voltage Vboost is applied is more than the certain number N, the step-up voltage is set to the voltage ΔVpgm# (<ΔVpgm) (step S16). The write voltage Vpgm is increased by the step-up voltage and the write voltage Vpgm is applied again to the memory cell MC (step S12).

FIG. 11 illustrates the write voltage Vpgm at the time of the write operation according to this embodiment. As illustrated in FIG. 11, in a first period after the write operation starts, the write voltage Vpgm is increased by the step-up voltage ΔVpgm (for example, 0.3 V), whenever the write voltage application operation is repeated. In a second period after the number of memory cells MC where the write operation ends, that is, the number of memory cells MC where the voltage Vboost is applied to the channel through the bit line BL is more than the certain number, the step-up voltage is set to the voltage ΔVpgm# (<ΔVpgm).

As described above, the voltage of the floating gate electrode of the selected memory cell MC at the time of the write operation is increased by the write voltage Vpgm with respect to the word line WL and the voltage of the adjacent floating gate electrode. In this case, even though the voltage Vboost is applied to the channel of the adjacent memory cell MC, the voltage of the floating gate electrode of the selected memory cell MC can be prevented from increasing by suppressing the step-up voltage of the write voltage Vpgm with respect to the word line WL to the voltage ΔVpgm#. The number of memory cells MC where the voltage Vboost is applied to the channel of the adjacent memory cell MC can be determined on the basis of the number of memory cells MC where the voltage Vboost is applied to the channel. In particular, when so-called randomizing processing is executed, the number of memory cells MC where the voltage Vboost is applied to the adjacent channel can be accurately determined on the basis of the number of memory cells MC where the voltage Vboost is applied to the channel.

[Effect]

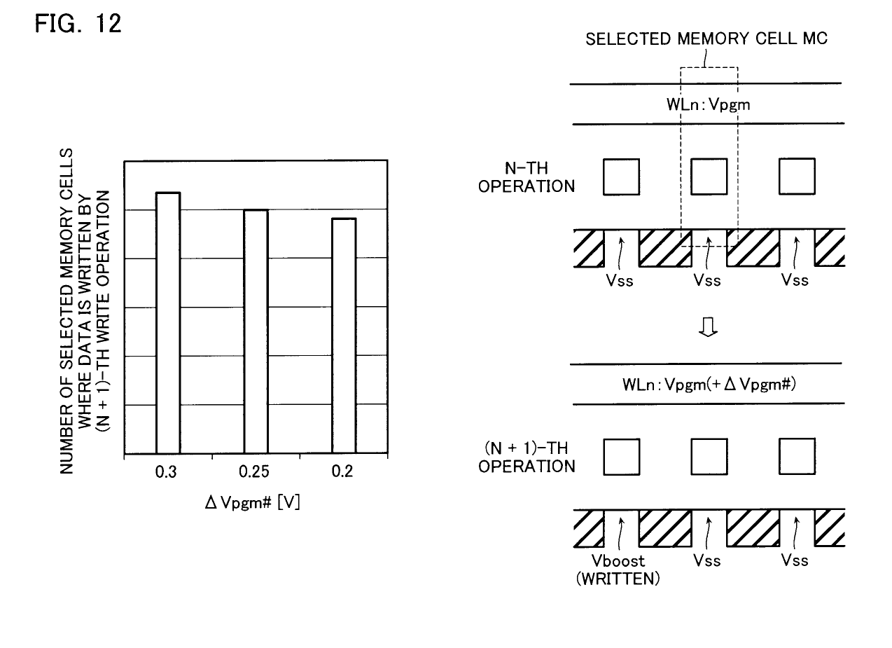

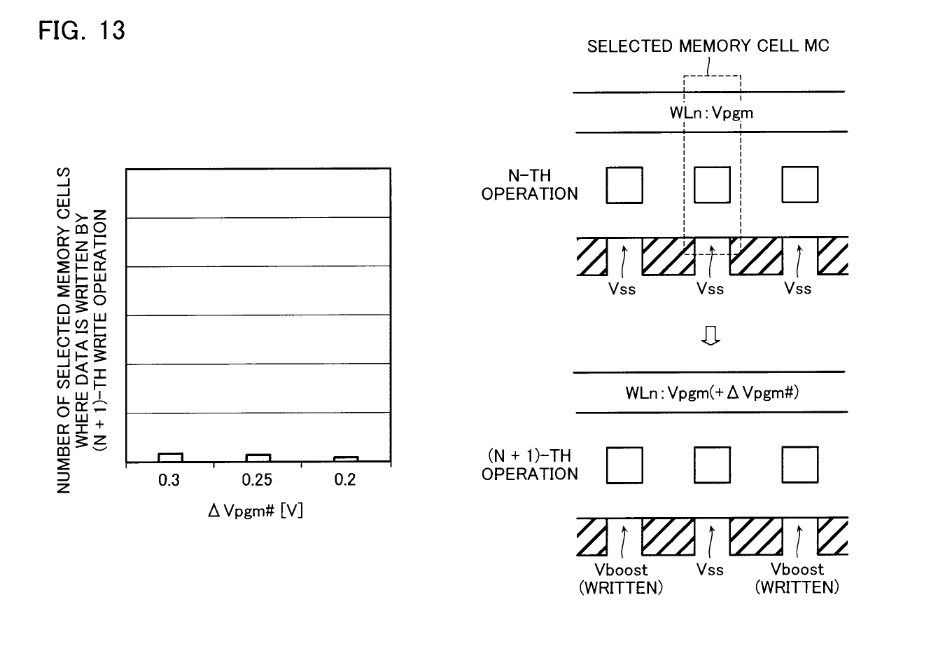

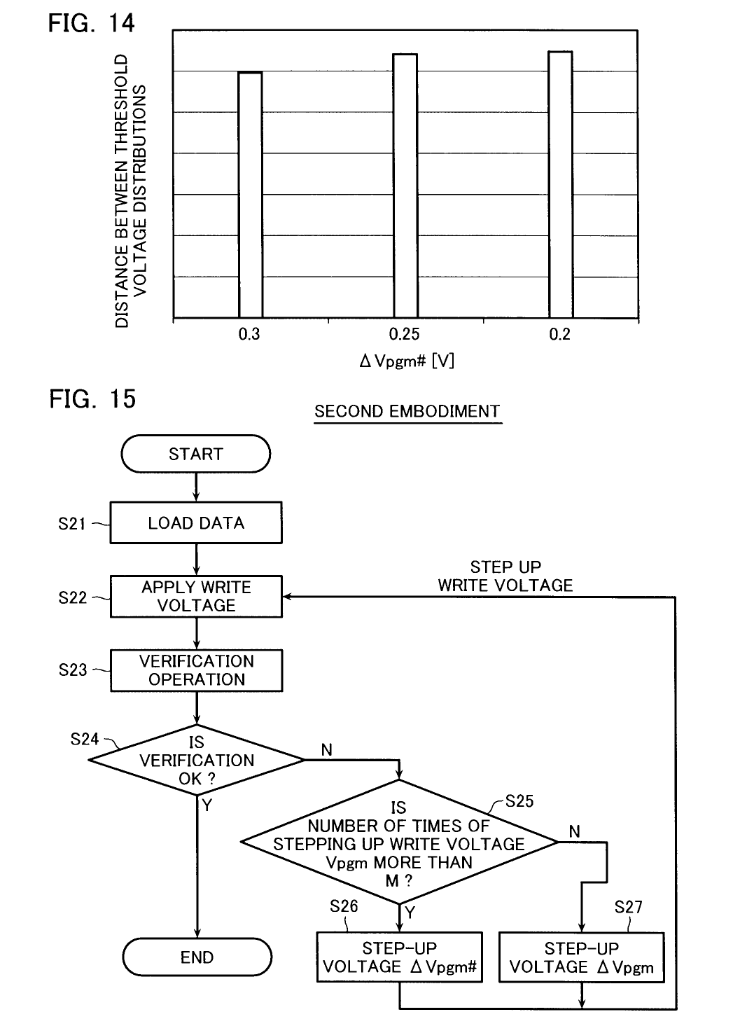

An effect of the write operation will be described with reference to FIGS. 12 to 14. FIGS. 12 and 13 are graphs illustrating the number of the selected memory cells MC in the case where the voltage Vboost is applied to the channel of the adjacent memory cell MC after an N-th application operation of the write voltage Vpgm and data is written in the selected memory cell MC by an (N+1)-th application operation of the write voltage Vpgm. FIG. 12 illustrates the case where data is written in the adjacent memory cell MC of the single side after the N-th application operation of the write voltage Vpgm and the voltage Vboost is applied to the channel of the adjacent memory cell MC of the single side at the time of the (N+1)-th application operation of the write voltage Vpgm. FIG. 13 illustrates the case where data is written in the adjacent memory cells MC of both sides after the N-th application operation of the write voltage Vpgm and the voltage Vboost is applied to the channels of the adjacent memory cells MC of both sides at the time of the (N+1)-th application operation of the write voltage Vpgm. The graphs of FIGS. 12 and 13 illustrate the number of selected memory cells MC that become the final change memory cells MCE at the time of the (N+1)-th application operation of the write voltage Vpgm. The graphs of FIGS. 12 and 13 illustrate a state of the case where the voltages ΔVpgm# are set to 0.3 V (that is, the case where the voltage does not change from the voltage ΔVpgm), 0.25 V, and 0.2 V, respectively.

As illustrated in FIGS. 12 and 13, when the voltage ΔVpgm# is set to 0.3 V (that is, the case where the voltage does not change from the voltage ΔVpgm), the number of selected memory cells MC that become final change memory cells MCE at the time of the (N+1)-th application operation of the write voltage Vpgm is largest. As described with reference to FIG. 8, the threshold voltage of the memory cell MC greatly changes when the voltage Vboost is applied to the channel of the adjacent memory cell MC. For this reason, the threshold voltage of the memory cell MC where data is written at the time of the (N+1)-th application operation of the write voltage becomes higher than the desired threshold voltage and this widens the threshold voltage distribution. Meanwhile, when the voltage ΔVpgm# is set to the voltage (0.25 V or 0.2 V) lower than the voltage ΔVpgm, the number of memory cells MC that become the final change memory cells MCE at the time of the (N+1)-th application operation of the write voltage Vpgm decreases. That is, the number of memory cells MC where data is written at timing when the voltage Vboost is applied to the channel of the adjacent memory cell MC and the threshold voltage of the memory cell MC greatly changes decreases. As a result, the threshold voltage distribution can be suppressed from being widened.

FIG. 14 is a graph illustrating the distances between the threshold voltage distributions, when the step-up voltages ΔVpgm# are set to 0.3 V (that is, the case where the voltage does not change from the voltage ΔVpgm), 0.25 V, and 0.2 V and the write operation ends. As illustrated in FIG. 14, when the step-up voltage ΔVpgm# is set to the voltage lower than the voltage ΔVpgm, the distances between the threshold voltage distributions after the write operation increase. As such, the distances between the threshold voltage distributions increase and erroneous read can be suppressed.

### Second Embodiment

Next, a non-volatile semiconductor storage device according to a second embodiment will be described with reference to FIG. 15. The entire configuration of the non-volatile semiconductor storage device according to the second embodiment is the same as that of the first embodiment and the overlapped description is omitted. The components similar to those of the first embodiment are denoted by the same reference numerals and the overlapped description is omitted.

In the first embodiment, when the number of bit lines BL where the voltage Vboost is applied is more than the certain number N, the step-up voltage is set to the voltage Vpgm# (<ΔVpgm). Meanwhile, the non-volatile semiconductor storage device according to the second embodiment is different from that of the first embodiment in that the step-up voltage is set to the voltage Vpgm# (<ΔVpgm), when the number of times of stepping up the write voltage Vpgm is more than the certain number of times.

The write operation according to this embodiment will be described with reference to FIG. 15. FIG. 15 is a flowchart illustrating a write operation according to this embodiment. An operation (steps S21 to S24) until the result of a verification operation is determined after the write operation starts is the same as the corresponding operation (steps S11 to S14 of FIG. 10) of the first embodiment.

During the verification operation, when it is determined that the threshold voltage of the selected memory cell MC is the certain verification voltage or less and data is not written in the selected memory cell MC (N in step S24), the process proceeds to an operation for counting the number of times of stepping up the write voltage Vpgm (step S25). When the number of times of stepping up the write voltage Vpgm is the certain number M or less, the step-up voltage is set to the voltage ΔVpgm (for example, 0.3 V). When the number of times of stepping up the write voltage Vpgm is more than the certain number M, the step-up voltage is set to the voltage Vpgm# (<ΔVpgm) (steps S26 and S27). The write voltage Vpgm is increased by the step-up voltage and the write voltage Vpgm is applied again to the memory cell MC (step S22).

[Effect]

In this embodiment, the voltage ΔVpgm# is set to the voltage lower than the voltage ΔVpgm, and the number of memory cells MC where data is written at timing when the voltage Vboost is applied to the channel of the adjacent memory cell MC and the threshold voltage of the memory cell MC greatly changes decreases. As a result, the threshold voltage distribution width can be suppressed from increasing. That is, the distances between the threshold voltage distributions after the write operation can be increased and erroneous read can be decreased.

In this case, the number of times of stepping up the write voltage Vpgm can be set by investigating the number of times of stepping up the write voltage Vpgm where the number of memory cells MC having passed the verification is maximized, by an inspection before shipping the semiconductor storage device. By setting the step-up voltage to the voltage Vpgm# from the next time after the number of memory cells MC where data is written is maximized, the threshold voltage of the data non-written memory cell MC can be prevented from greatly changing.

### Third Embodiment

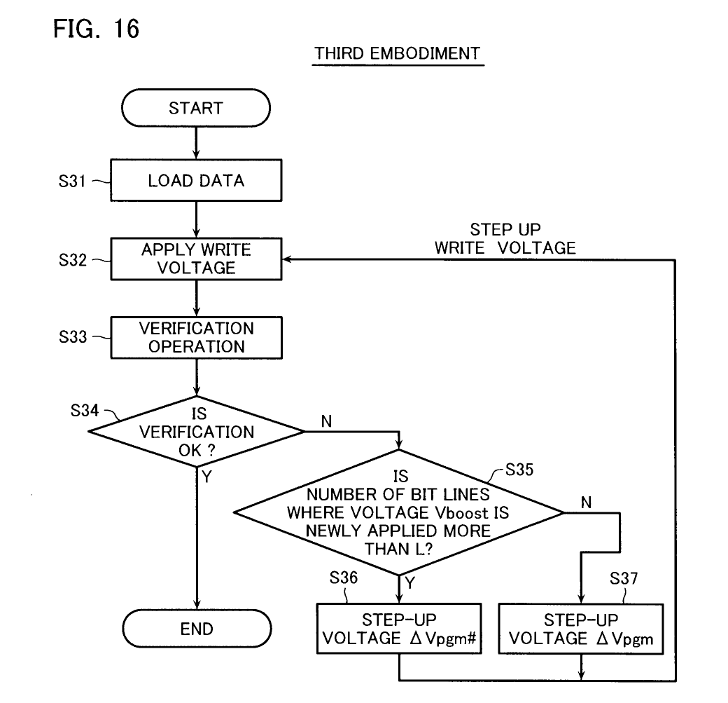

Next, a non-volatile semiconductor storage device according to a third embodiment will be described with reference to FIG. 16. The entire configuration of the non-volatile semiconductor storage device according to the third embodiment is the same as that of the first embodiment and the overlapped description is omitted. The components similar to those of the first and second embodiments are denoted by the same reference numerals and the overlapped description is omitted.

In the first embodiment, the step-up voltage (voltage ΔVpgm) is changed on the basis of the number of bit lines BL where the voltage Vboost is applied. Meanwhile, in the third embodiment, after applying the write voltage to which the step-up voltage is added, the voltage ΔVpgm is changed on the basis of the number of bit lines BL where the voltage Vboost is newly applied. This configuration is different from that of the first embodiment.

The write operation according to this embodiment will be described with reference to FIG. 16. FIG. 16 is a flowchart illustrating the write operation according to this embodiment. An operation (steps S31 to S34) until the result of a verification operation is determined after the write operation starts is the same as the corresponding operation (steps S11 to S14 of FIG. 10) of the first embodiment.

During the verification operation, when it is determined that the threshold voltage of the selected memory cell MC is the certain verification voltage or less and data is not written in the selected memory cell MC (N in step S34), the process proceeds to an operation for counting the number of bit lines BL where the voltage Vboost is newly applied (step S35). The number of memory cells MC where the write operation newly ends can be found by counting the number of write completion flags PF (corresponding to the number of bit lines BL where the voltage Vboost is applied) of which a level changes from an “L” level to an “H” level.

When the number of bit lines BL where the voltage Vboost is newly applied is the certain number L or less, the step-up voltage is maintained at the voltage ΔVpgm (for example, 0.3 V), the write voltage is stepped up, and the write voltage is applied to the memory cell MC (step S37). When the number of bit lines BL where the voltage Vboost is newly applied is more than the certain number L, the step-up voltage is set to the voltage ΔVpgm# (<ΔVpgm) (step S36). The write voltage Vpgm is increased by the step-up voltage and the write voltage Vpgm is applied again to the memory cell MC (step S32).

In the write operation according to this embodiment, timing when a period (first period) where the step-up voltage ΔVpgm is applied and a period (second period) where the step-up voltage ΔVpgm# is applied are switched may arise several times.

[Effect]

In this embodiment, the voltage ΔVpgm# is set to the voltage lower than the voltage ΔVpgm, and the number of memory cells MC where data is written at timing when the voltage Vboost is applied to the channel of the adjacent memory cell MC and the threshold voltage of the memory cell MC greatly changes decreases. As a result, the threshold voltage distribution width can be suppressed from increasing. That is, the distances between the threshold voltage distributions after the write operation can be widened and erroneous read can be decreased.

By controlling the step-up voltage on the basis of the number of memory cells MC where the write operation newly ends, the threshold voltage distribution width can be accurately suppressed from increasing. A general threshold voltage distribution is the distribution illustrated in FIG. 4. For this reason, the number of memory cells MC where the write operation newly ends is maximized at the certain number of times of loop. Therefore, as in the first embodiment, even though the step-up voltage is controlled according to the number of memory cells MC where the write operation newly ends, the threshold voltage distribution width can be suppressed from increasing.

However, in practice, the threshold voltage distribution may not become the normal-distribution illustrated in FIG. 4. For example, a plurality of peak values of the threshold voltage distribution may appear. In this case, the number of memory cells MC where the write operation newly ends also has a plurality of peak values. Therefore, by controlling the step-up voltage on the basis of the number of memory cells MC where the write operation newly ends, the threshold voltage distribution width can be accurately suppressed from increasing, even though the threshold voltage distribution does not become the normal-distribution.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions. For example, in the embodiments described above, the non-volatile semiconductor storage device of the four-valued storage system (2 bits/cell) is used. However, the invention is not limited thereto and the invention may be applied to multi-bit storage systems such as an eight-valued storage system. The invention may be applied to a so-called MONOS-type memory cell in which the electrons are trapped in an insulating film, not using the floating gate electrode as the charge accumulating layer.

What is claimed is:

1. A non-volatile semiconductor storage device, comprising:
a memory cell array that has NAND cell units in which a plurality of memory cells each having a control gate and a charge accumulating layer are connected in series, one end of the NAND cell unit being connected to a bit line through a first select gate transistor, the other end thereof being connected to a source line through a second select gate transistor, the control gate of each of the plurality of memory cells being connected to a word line and gates of the first and second select gate transistors being respectively connected to first and second select gate lines; and
a control circuit configured to execute a write operation by applying a certain write voltage to the word line multiple times to set a threshold voltage of the memory cell to a value corresponding to data, the control circuit being configured to control the write voltage such that the write voltage is increased by a first step-up voltage when the write voltage is repeatedly applied in a first period after the write operation starts, and the write voltage is increased by a second step-up voltage lower than the first step-up voltage in a second period after the first period.

2. The non-volatile semiconductor storage device according to claim 1,
wherein the control circuit transits from the first period to the second period when the number of memory cells whose channel is applied with a certain voltage through the bit line at the time of the write operation is more than a certain number.

3. The non-volatile semiconductor storage device according to claim 1,
wherein the control circuit transits from the first period to the second period when the write voltage is applied to the word line a certain number of times.

4. The non-volatile semiconductor storage device according to claim 1,
wherein the control circuit transits from the first period to the second period when the number of memory cells whose write operation is newly prohibited after applying the write voltage is more than a certain number.

5. The non-volatile semiconductor storage device according to claim 1,
wherein the control circuit executes the write operation with respect to all of the memory cells connected to one word line.

6. The non-volatile semiconductor storage device according to claim 1,
wherein the control circuit executes a verify operation to verify whether the memory cell attains a certain threshold voltage after the write operation is executed.

7. The non-volatile semiconductor storage device according to claim 1,
wherein the control circuit includes a sense amplifier circuit provided for each bit line, the sense amplifier circuit outputting a write completion signal when certain voltage is applied to the bit line at the time of the write operation.

8. The non-volatile semiconductor storage device according to claim 1,
wherein the memory cell is configured to be capable of storing a multi-valued data of multi-bit.

9. A non-volatile semiconductor storage device, comprising:
a memory cell array that has NAND cell units in which a plurality of memory cells each having a control gate and a charge accumulating layer are connected in series, one end of the NAND cell unit being connected to a bit line through a first select gate transistor, the other end thereof being connected to a source line through a second select gate transistor, the control gate of each of the plurality of memory cells being connected to a word line and gates of the first and second select gate transistors being connected to first and second select gate lines, respectively; and
a control circuit configured to execute a write operation by applying a certain write voltage to the word line multiple times to set a threshold voltage of the memory cell to a value corresponding to data, when the write voltage is repeatedly applied, the control circuit being configured to control the write voltage such that the write voltage is increased by a first step-up voltage when the number of memory cells whose write operation is newly prohibited after applying the write voltage is equal to or less than a certain number, and the write voltage is increased by a second step-up voltage lower than the first step-up voltage when the number of memory cells whose write operation is newly prohibited after applying the write voltage is more than a certain number.

10. The non-volatile semiconductor storage device according to claim 9,
wherein the control circuit executes the write operation with respect to all of the memory cells connected to one word line.

11. The non-volatile semiconductor storage device according to claim 9,
wherein the control circuit executes a verify operation to verify whether the memory cell attains a certain threshold voltage after the write operation is executed.

12. The non-volatile semiconductor storage device according to claim 9,
wherein the control circuit includes a sense amplifier circuit provided for each bit line, the sense amplifier circuit outputting a write completion signal when certain voltage is applied to the bit line at the time of the write operation.

13. The non-volatile semiconductor storage device according to claim 12,
wherein the control circuit counts the number of memory cells whose write operation is newly prohibited after applying the write voltage based on the write completion signal.

14. The non-volatile semiconductor storage device according to claim 9,
wherein the memory cell is configured to be capable of storing a multi-valued data of multi-bit.

15. A non-volatile semiconductor storage device, comprising:
a memory cell array that has NAND cell units in which a plurality of memory cells each having a control gate and a charge accumulating layer are connected in series, one end of the NAND cell unit being connected to a bit line through a first select gate transistor, the other end thereof being connected to a source line through a second select gate transistor, the control gate of each of the plurality of memory cells being connected to a word line and gates of the first and second select gate transistors being connected to first and second select gate lines, respectively; and
a control circuit configured to execute a write operation by applying a certain write voltage to the word line multiple times to set a threshold voltage of the memory cell to a value corresponding to data, when the write voltage is repeatedly applied, the control circuit being configured to be capable of controlling the step-up value of the write voltage based on the number of memory cells whose channel is applied with a certain voltage through the bit line at the time of the write operation.

16. The non-volatile semiconductor storage device according to claim 15,
wherein the control circuit controls the write voltage such that the write voltage is increased by a first step-up voltage when the number of memory cells whose channel is applied with a certain voltage through the bit line at the time of the write operation is equal to or less than a certain number, and the write voltage is increased by a second step-up voltage lower than the first step-up voltage when the number of memory cells whose channel is applied with a certain voltage through the bit line at the time of the write operation is more than a certain number.

17. The non-volatile semiconductor storage device according to claim 15,
wherein the control circuit executes the write operation with respect to all of the memory cells connected to one word line.

18. The non-volatile semiconductor storage device according to claim 15,
wherein the control circuit executes a verify operation to verify whether the memory cell attains a certain threshold voltage after the write operation is executed.

19. The non-volatile semiconductor storage device according to claim 15,
wherein the control circuit includes a sense amplifier circuit provided for each bit line, the sense amplifier circuit outputting a write completion signal when certain voltage is applied to the bit line at the time of the write operation.

20. The non-volatile semiconductor storage device according to claim 19,
wherein the control circuit counts the number of memory cells whose channel is applied with a certain voltage through the bit line at the time of the write operation based on the write completion signal.
